(19) United States
(12) Patent Application Publication
(10) Pub. No.: US 2002/0021148 A1
(43) Pub. Date: Feb. 21, 2002

(54) CURRENT CONTROL OF OUTPUT SWING

(76) Inventors: DAVID GOREN, NESHER (IL); MICHAEL ZELIKSON, HAIFA (IL); VIKTOR ARIEL, TEL AVIV (IL)

Correspondence Address: DARBY & DARBY, 805 THIRD AVENUE, NEW YORK, NY, 10022

(21) Appl. No.: 09/268,015

(22) Filed: Mar. 15, 1999

(51) Int. Cl. H03K 5/22

(52) U.S. Cl. 327/65

(57) ABSTRACT

A variable output voltage swing differential driver including an open-loop current control unit operative to produce a control current, and a voltage output unit receiving the control current and operative to produce a voltage output having a variable output swing.

Related apparatus and methods are also disclosed.

### FIELD OF THE INVENTION

The present invention relates to circuit testing equipment in general, and in particular to drivers for use with integrated circuit testing equipment.

### BACKGROUND OF THE INVENTION

Integrated circuit (IC) testing equipment is well-known in the art. One typical example of IC testing equipment is described in Takashi Sekino and Toshiyuki Okayasu, “Ultra Hi-Speed Pin-Electronics and Test Station using GaAs IC”, International Test Conference 1994, paper 29.1, pages 683-690.

One example of commercially available IC testing equipment is the Duo™ system, commercially available from Credence Systems Corporation, 3500 West Warren Avenue, Fremont Calif. 94538. The Duo™ system is described in a document entitled Duo™ System Description, dated 1995. It is appreciated that the Duo™ system is only one particular example of commercially available IC testing equipment, and that there are other examples.

It is well known in the prior art that an IC under test typically includes a plurality of pins for communication with the IC, and that an appropriate hardware driver must typically be provided to drive each pin to be tested of the IC under test. Each hardware driver is typically implemented in a driver IC, often with additional control circuitry being located off-chip, typically on a pin electronics card. Each driver must be capable, in response to a signal received from the IC testing device, of driving the pin to which the driver is attached with an appropriate voltage, typically variable with a predefined voltage swing, based on the specification of the IC under test. Often, a variable voltage swing is required, particularly in order to allow testing of different ICs.

For testing modern ICs, which typically operate at very high frequency, the ability of the driver to accurately switch voltage over the voltage swing, at very high frequency and with only a small error in voltage, is known to be important.

A typical prior art driver last stage is shown in FIG. 1. In the prior art system of FIG. 1 a closed-loop analog voltage control unit (VCU) 100 is used to control the voltage swing. Typically, the prior art VCU 100 includes an operational amplifier 110, typically implemented off-chip, which provides feedback needed to stabilize the prior art VCU 100.

The disclosures of all references mentioned above and throughout the present specification are hereby incorporated herein by reference.

### SUMMARY OF THE INVENTION

The present invention seeks to provide an improved driver for use with integrated circuit (IC) testing equipment.

The typical prior art driver described above with reference to FIG. 1 has serious drawbacks. The operational amplifier 110 is necessary to stabilize the circuit, which is non-linear and is sensitive to technology process variations. Use of an off-chip feedback circuit significantly increases the complexity and cost of the driver.

In the present invention, an analog current signal is used to control the driver output swing. The present invention provides open loop linear control which is nearly independent of temperature and technology variations. The need for a feedback circuit is thus eliminated in the present invention, and no off-chip control circuitry is necessary for this purpose. The present invention is also believed to provide more accurate swing control than devices known in the prior art.

The present invention is believed to be useful independent of the technology used for driver implementation and can, for example, be applied to CMOS, NMOS, and BICMOS technologies and can be implemented in Si, SiGe, GaAs, or any other appropriate semiconductor material.

While the present invention is particularly useful for IC test equipment such as automatic probe stations for testing fast VLSI chips, it is appreciated that the present invention may be generally used in any differential driver with variable output voltage swing.

There is thus provided in accordance with a preferred embodiment of the present invention a variable output voltage swing differential driver including an open-loop current control unit operative to produce a control current, and a voltage output unit receiving the control current and operative to produce a voltage output having a variable output swing.

Further in accordance with a preferred embodiment of the present invention the voltage output unit includes a differential transistor pair.

Still further in accordance with a preferred embodiment of the present invention the open-loop current control unit includes a current mirror.

Additionally in accordance with a preferred embodiment of the present invention the open-loop control current unit and the voltage output unit are implemented on a single integrated circuit chip.

Moreover in accordance with a preferred embodiment of the present invention the apparatus also includes chip-connection apparatus for connecting the voltage output to an external IC under test.

Further in accordance with a preferred embodiment of the present invention the open-loop current control unit is operative to receive an external current control signal.

There is also provided in accordance with another preferred embodiment of the present invention IC testing apparatus for variable output voltage swing testing of an IC, the apparatus including control signal generating apparatus operative to generate a current control signal, an open-loop current control unit receiving the current control signal and operative to produce a control current based on the current control signal, a voltage output unit receiving the control current and operative to produce a voltage output having an output swing, and chip-connection apparatus for connecting the voltage output to an external IC under test.

Further in accordance with a preferred embodiment of the present invention the voltage output unit includes a differential transistor pair.

Still further in accordance with a preferred embodiment of the present invention the output swing is at least approximately 3V.

Additionally in accordance with a preferred embodiment of the present invention the output swing has an associated error, and the error is no more than approximately 5 mV.

Moreover in accordance with a preferred embodiment of the present invention the output swing has an error and the error is no more than approximately 1 part in 300.

There is also provided in accordance with another preferred embodiment of the present invention a method for producing a variable output voltage swing, the method including providing an open-loop current control unit, producing a control current using the open-loop current control unit, and producing, based on the control current, a voltage output having a variable output swing.

There is also provided in accordance with another preferred embodiment of the present invention an IC testing method for variable output voltage swing testing of an IC, the method including generating a current control signal, providing an open-loop current control unit, receiving the current control signal at the current control unit and producing a control current based on the current control signal, receiving the control current and producing a voltage output having an output swing, and connecting the voltage output to an external IC under test.

### BRIEF DESCRIPTION OF THE DRAWINGS

The present invention will be understood and appreciated more fully from the following detailed description, taken in conjunction with the drawings in which:

FIG. 1 is a simplified schematic illustration of a prior art differential driver;

FIG. 2 is a simplified schematic illustration of a differential driver constructed and operative in accordance with a preferred embodiment of the present invention;

FIG. 3 is a simplified schematic illustration of a driver circuit particularly useful in conjunction with the apparatus of FIG. 2;

FIG. 4 is a simplified schematic illustration of a preferred illustration of the receiver 170 of FIG. 3;

FIG. 5 is a simplified schematic illustration of an on-chip power supply useful in conjunction with the apparatus of FIG. 4;

FIG. 6 is a simplified schematic illustration of a preferred implementation of the preamplifier 180 of FIG. 3; and

FIG. 7 is a simplified schematic illustration of a preferred implementation of the driver 190 of FIG. 3.

### DETAILED DESCRIPTION OF A PREFERRED EMBODIMENT

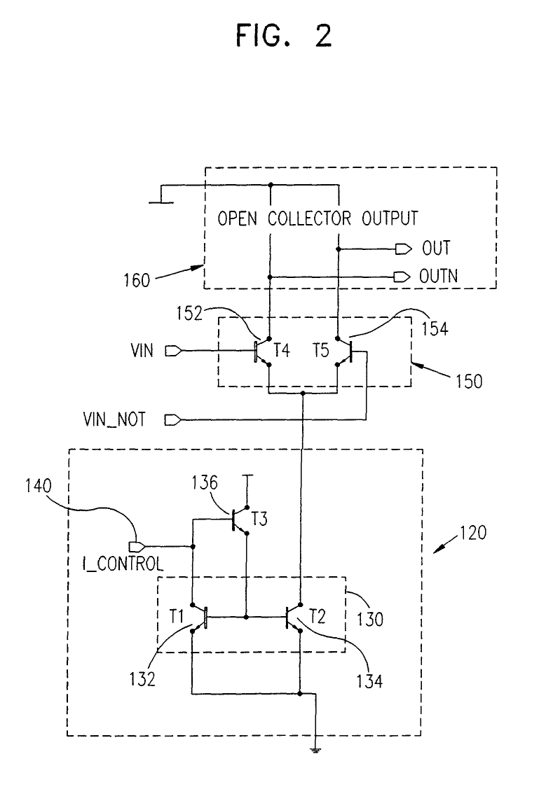

Reference is now made to FIG. 2 which is a simplified schematic illustration of a differential driver constructed and operative in accordance with a preferred embodiment of the present invention. The apparatus of FIG. 2, in addition to conventional elements known in the prior art, comprises an open-loop current control unit 120. The open-loop current control unit 120 typically comprises a current-control subunit, typically comprising a current mirror 130, as shown in FIG. 2. The open-loop current control unit 120 is operative to produce a control current based on an external current control signal received at a connection point 140.

A current mirror is a device, well-known in the art, typically used in IC current sources, for providing an output current from a given input current. Typically a current mirror comprises two matched transistors with their bases and emitters coupled together, such as transistor T1 132 and transistor T2 134. Transistor T3 136 provides a better matching between the external control signal received at the connection point 140 and the collector current of transistor T2 134.

The apparatus of FIG. 2 also comprises a differential transistor pair 150, comprising a transistor T4 152 and a transistor T5 154. The differential transistor pair 150 is connected to the output of the open-loop current control unit 120 and receives the control current therefrom. The differential transistor pair 150 produces a voltage output having a variable output swing, as is well known in the art.

It is appreciated that, in the apparatus of FIG. 2 the output swing is controlled by the control current and thus is controlled directly by the open-loop current control unit 120, without voltage-to-current conversion.

The apparatus of FIG. 2 typically comprises chip connection apparatus 160 for connecting the apparatus of FIG. 2 to a pin of an IC under test.

The operation of the apparatus of FIG. 2 is now briefly described. An external current control signal is applied to the open-loop current control unit 120, typically by an IC testing unit. The open-loop current control unit 120 is operative to produce a control current which is, as is described more fully below, generally linearly related to the external current control signal.

The control current is applied to the differential transistor pair 150, which produces a voltage output which is generally linearly related to the control current. Thus, linear control of the voltage output is achieved.

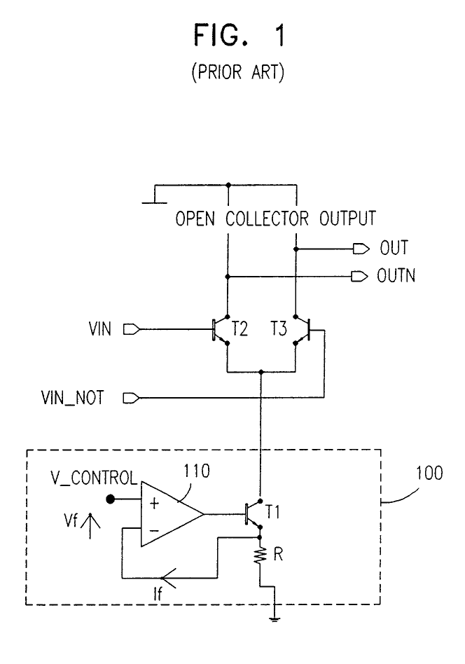

The ability of the apparatus of FIG. 2 to control the output swing with high accuracy is believed to be significantly greater than that of the prior art apparatus of FIG. 1. The greater accuracy of the apparatus of FIG. 2 may be appreciated from the following discussion.

Referring back to prior art FIG. 1, the collector current of transistor T2, referred to as IO, which controls the output swing, is given by the following equation:

IO=(β1/(β1+1))*(((Vcontrol−Vf)/R)+If)

where:

β1 is the current gain of transistor T1;

Vf is the sum of:

the input offset voltage of the operational amplifier; and

the operational amplifier's output voltage divided by the operational amplifier's output gain;

If is the input current to the operational amplifier; and

R is the resistance of the resistor in FIG. 1.

It will be appreciated by a person skilled in the art that, for small Vf and If, IO is almost directly proportional to Vcontrol. However, the offset voltage Vf can vary in time and may need recalibration. It will also be appreciated that IO is sensitive to variations in various parameters of the components of the apparatus of FIG. 1, such as the current gain β1 and the resistance R. Such variations may occur for a variety of reasons, including, for example: chip to chip statistical variations; statistical deviations in the parameters between similar components on a single chip; changes at different current densities, such as decrease in β1 at high output currents; and changes due to operating temperature differences.

It will further be appreciated that IO can vary significantly with variations in R, which may vary in practice as much as 20% from chip to chip. Variations in β1 from chip to chip, which may be as large as 100%, may also be significant. Variations due to current density may affect β1 by as much as 30%; β1 also tends to vary according to temperature, and the amount of variation per degree tends to be greater at higher temperatures.

Referring now again to FIG. 2, the collector current IO of the T2 transistor is given by:

IO=Icontrol*((1+β1)/β1)*(β2/(1+⊖2))*(Ies2/Ies1)*(Ae2/Ae1)

where:

Icontrol is the control current;

Iesn is the base-emitter junction Ebers-Moll equation coefficient for transistor n; and

Aen is the emitter area for transistor n.

It is appreciated, therefore, that in the embodiment of FIG. 2 IO is directly proportional to the control current Icontrol, without a disturbance to the linear relationship such as that in the prior art case, particularly due to Vf and If in the prior art case.

It is further appreciated that in the embodiment of FIG. 2 variations in IO occur only due to differences between the transistors T1 and T2. Since, in practice, factors affecting either T1 or T2 will equally affect both T1 and T2, the influence of such changes tends to cancel. For example, changes in temperature and current density can be expected to cause the same changes in β1 as in β2, and the changes will cancel.

Preferably, to make T1 and T2 as similar as possible, T1 and T2 may be fabricated close to each other on one chip. In an embodiment where each of T1 and T2 comprises a plurality of smaller transistors connected in parallel, it is preferred to use alternating positions of T1 and T2 transistors in the circuit layout to further reduce the variation between T1 and T2.

It is thus seen that the accuracy of the apparatus of FIG. 2 can be expected to exceed that of prior art circuits designed to perform a similar function.

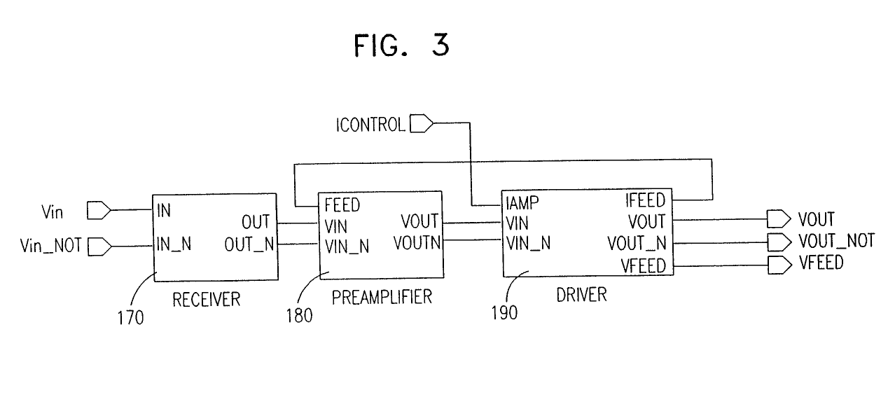

It is appreciated that the differential driver of FIG. 2 will typically be used as part of a larger driver circuit. Reference is now made to FIG. 3, which is a simplified schematic illustration of a driver circuit particularly useful in conjunction with the apparatus of FIG. 2. The apparatus of FIG. 3 comprises one particular example of a driver circuit useful in conjunction with the apparatus of FIG. 2, and the example is not meant to be limiting. The apparatus of FIG. 3 preferably comprises a receiver 170, a preamplifier 180, and a driver 190.

Reference is now additionally made to the following figures:

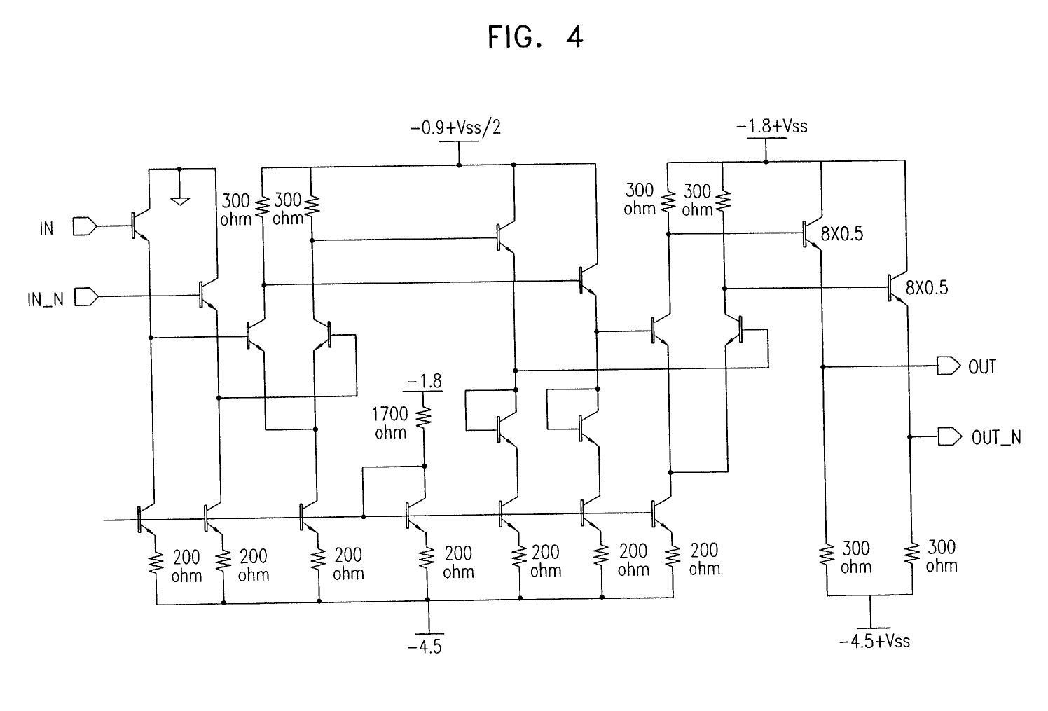

FIG. 4, which is a simplified schematic illustration of a preferred illustration of the receiver 170 of FIG. 3;

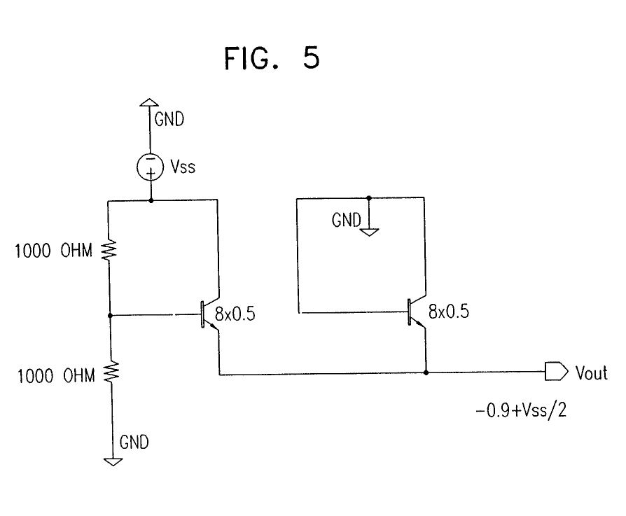

FIG. 5, which is a simplified schematic illustration of an on-chip power supply useful in conjunction with the apparatus of FIG. 4;

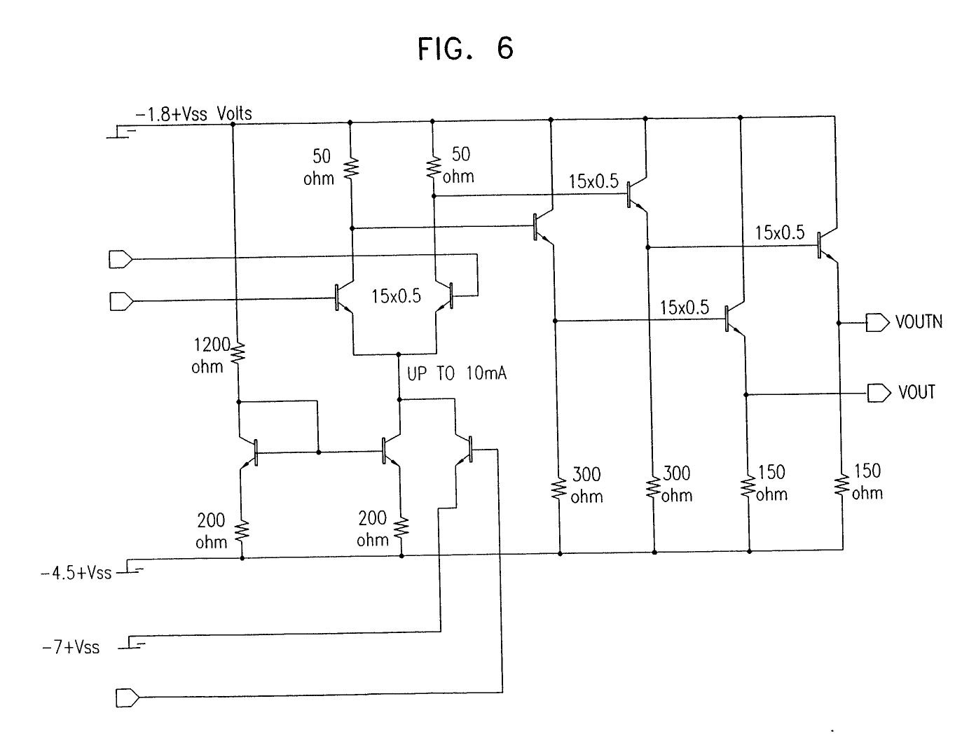

FIG. 6, which is a simplified schematic illustration of a preferred implementation of the preamplifier 180 of FIG. 3; and

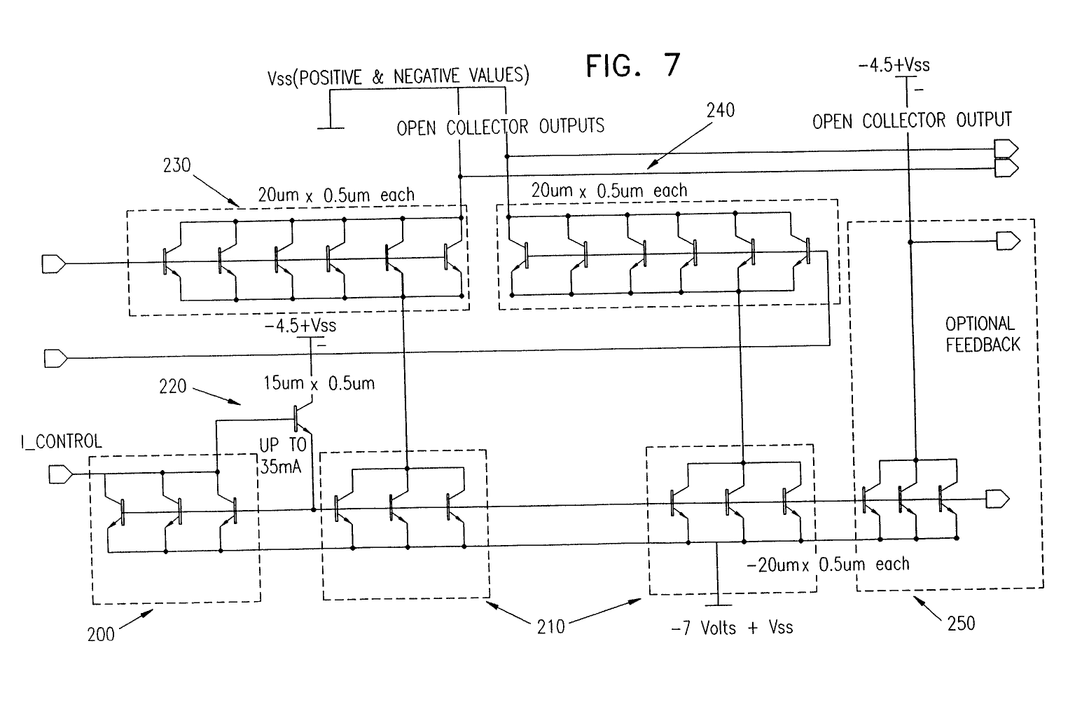

FIG. 7, which is a simplified schematic illustration of a preferred implementation of the driver 190 of FIG. 3.

Except as described below, FIGS. 3-7 are self-explanatory.

In FIG. 4, transistor sizes are 2.5 μm×0.5 μm unless otherwise shown.

In FIG. 5, Vss typically comprises a variable external power supply preferably having a voltage range between approximately −2 volts and approximately +4 volts.

The apparatus of FIG. 7 comprises an alternative preferred embodiment of the apparatus of FIG. 2. It will be appreciated by a person skilled in the art that various elements comprised in the apparatus of FIG. 7 correspond to elements of FIG. 2 as follows:

| | |
|---|---|
| 200 | 132 |
| 210 | 134 |
| 220 | 136 |
| 230 | 152 |
| 240 | 154 |

The apparatus of FIG. 7 also comprises a feedback subcircuit 250 for providing additional control of the apparatus of FIG. 7. It is appreciated that the feedback subcircuit 250 is optional, and that a feedback subcircuit is not generally required in the present invention.

Typically, the apparatus of FIGS. 3-7 is capable of testing an IC at a rate of 2.5 GHz or more, with a typically voltage swing of 3V and a voltage error of no more than 5 mV.

It is appreciated that various features of the invention which are, for clarity, described in the contexts of separate embodiments may also be provided in combination in a single embodiment. Conversely, various features of the invention which are, for brevity, described in the context of a single embodiment may also be provided separately or in any suitable subcombination.

It will be appreciated by persons skilled in the art that the present invention is not limited by what has been particularly shown and described hereinabove. Rather the scope of the invention is defined only by the claims which follow:

What is claimed is:

1. A variable output voltage swing differential driver comprising:
an open-loop current control unit operative to produce a control current; and
a voltage output unit receiving the control current and operative to produce a voltage output having a variable output swing.

2. Apparatus according to claim 1 and wherein the voltage output unit comprises a differential transistor pair.

3. Apparatus according to claim 1 and wherein the open-loop current control unit comprises a current mirror.

4. Apparatus according to claim 1 and wherein the open-loop control current unit and the voltage output unit are implemented on a single integrated circuit chip.

5. Apparatus according to claim 1 and also comprising chip-connection apparatus for connecting the voltage output to an external IC under test.

6. Apparatus according to claim 1 and wherein the open-loop current control unit is operative to receive an external current control signal.

7. IC testing apparatus for variable output voltage swing testing of an IC, the apparatus comprising:
control signal generating apparatus operative to generate a current control signal;
an open-loop current control unit receiving the current control signal and operative to produce a control current based on the current control signal;
a voltage output unit receiving the control current and operative to produce a voltage output having an output swing; and
chip-connection apparatus for connecting the voltage output to an external IC under test.

8. Apparatus according to claim 7 and wherein the voltage output unit comprises a differential transistor pair.

9. Apparatus according to claim 7 and wherein the output swing is at least approximately 3V.

10. Apparatus according to claim 9 and wherein the output swing has an associated error, and the error is no more than approximately 5 mV.

11. Apparatus according to claim 7 and wherein the output swing has a n error and the error is no more than approximately 1 part in 300.

12. A method for producing a variable output voltage swing, the method comprising:
providing an open-loop current control unit;
producing a control current using the open-loop current control unit; and
producing, based on the control current, a voltage output having a variable output swing.

13. An IC testing method for variable output voltage swing testing of an IC, the method comprising:
generating a current control signal;
providing an open-loop current control unit;
receiving the current control signal at the current control unit and producing a control current based on the current control signal;
receiving the control current and producing a voltage output having an output swing; and
connecting the voltage output to an external IC under test.
